(19) United States
(12) Patent Application Publication
(10) Pub. No.: US 2014/0183488 A1
(43) Pub. Date: Jul. 3, 2014

(54) ORGANIC ELECTROLUMINESCENT COMPONENT

(71) Applicants: Daniel Steffen Setz, Böblingen (DE); Carola Diez, Regensburg (DE)

(72) Inventors: Daniel Steffen Setz, Böblingen (DE); Carola Diez, Regensburg (DE)

(73) Assignee: OSRAM Opto Semiconductors GmbH, Regensburg (DE)

(21) Appl. No.: 14/122,665

(22) PCT Filed: May 9, 2012
(86) PCT No.: PCT/EP2012/058501

§ 371 Date: Feb. 7, 2014

(30) Foreign Application Priority Data
May 31, 2011 (DE) 10 2011 076 791.6

(51) Int. Cl. H01L 51/50

(52) U.S. Cl. CPC H01L 51/5012
USPC 257/40

(57) ABSTRACT

The invention relates to an organic electroluminescent component having a first organic functional stack (1), which has a first electroluminescent layer (11) and at least one n-doped organic layer (12), and a second organic functional stack (2), which has a second electroluminescent layer (21) and at least one p-doped organic layer (23), wherein the n-doped and the p-doped organic layers (12, 23) are arranged between the first and second electroluminescent layers (11, 21) and a metal layer (3) is arranged therebetween, directly adjacent to the n-doped and the p-doped organic layers (12, 23).

An organic electroluminescent component is specified.

Organic light emitting diodes (OLED) are known which are, during operation, emissive on one side. In this case, one side of the OLED is embodied as reflective, while the other side, through which light is emitted, is transparent.

Furthermore, OLEDs are known which are emissive on both sides during operation and are transparent in the switched-off state. The light generated in an electroluminescent region is in this case usually emitted uniformly in the direction of both sides, such that the emission properties on the two sides cannot be set independently of one another.

In order to produce an OLED having emission properties that can be set separately from one another on both sides, usually two OLEDs that are emissive on one side are arranged with their reflective sides against one another and are operated independently of one another.

At least some embodiments are based on the object of specifying an organic electroluminescent component.

This object is achieved by means of an article comprising features in accordance with the following description. Advantageous embodiments and developments of the article are characterized in the claims and are furthermore evident from the following description and the drawings.

In accordance with at least one embodiment, an organic electroluminescent component comprises at least one organic functional stack. The at least one organic functional stack can be arranged in particular between a first electrode and a second electrode, via which electrical charge carriers, that is to say electrons and holes can be injected into the at least one organic functional stack. Furthermore, the at least one organic functional stack can be arranged on a substrate. The at least one organic functional stack can have in particular at least one and particularly preferably a plurality of organic functional layers. The latter can comprise or be composed of organic polymers, organic oligomers, organic monomers, organic small non-polymeric molecules (“small molecules”) or combinations thereof.

In accordance with a further embodiment, the organic electroluminescent component is embodied as an organic light emitting diode (OLED). For this purpose, the at least one organic functional stack has at least one electroluminescent layer in the form of an individual layer or in the form of an electroluminescent layer stack comprising a plurality of electroluminescent layers in which electrons and holes can recombine with generation of light. Here and hereinafter, light can denote in particular electromagnetic radiation in an ultraviolet to infrared spectral range and in particular in a visible spectral range.

Suitable materials for the at least one or the plurality of electroluminescent layers are, in particular, materials which exhibit radiation emission on account of fluorescence or phosphorescence, for example polyfluorene, polythiophene or polyphenylene or derivatives, compounds, mixtures or copolymers thereof. Alternatively or additionally, the at least one or the plurality of electroluminescent layers can also comprise small molecule materials which can generate light by means of fluorescence or phosphorescence.

In accordance with a further embodiment, the at least one organic functional stack has at least one doped layer. In this case, the doped layer can be formed by a p-doped layer or by an n-doped layer. P-doped and n-doped layers denote layers which are suitable for conducting holes and electrons, respectively, and, by way of example, in the case of a p-doped organic layer, can conduct holes from an anode to at least one electroluminescent organic layer and, in the case of an n-doped layer, can conduct electrons from a cathode to at least one electroluminescent organic layer. The organic functional layers of the at least one organic functional stack and in particular the p-doped and/or n-doped layers can comprise for example charge carrier transport layers, that is to say electron transport layers and/or hole transport layers, charge carrier blocking layers, that is to say electron blocking layers and/or hole blocking layers, and/or charge carrier injection layers, that is to say electron injection layers and/or hole injection layers, or can be formed by one or a plurality of such layers. Organic materials for functional layers of this type are known to the person skilled in the art and will therefore not be explained any further here.

In accordance with a further embodiment, the at least one organic functional stack has at least one electroluminescent organic layer and at least one doped organic layer, that is to say at least one n-doped organic layer and/or at least one p-doped organic layer. Particularly preferably, the at least one organic functional stack can have at least one electroluminescent organic layer arranged between at least one n-doped and at least one p-doped organic layer.

In accordance with a further embodiment, the organic electroluminescent component comprises a substrate, which is embodied as a plate or film and has one or a plurality of layers which comprise or are composed of glass, quartz, plastic, metal or a combination thereof. If the organic electroluminescent component is embodied as a so-called “bottom emitter”, that is to say that light generated in the at least one organic functional stack is emitted through the substrate, then the substrate can have a transparency to at least part of the light. In this case, the substrate can preferably comprise glass or a transparent plastic or be composed thereof.

In accordance with a further embodiment, at least one of the first and second electrodes is transparent to at least part of the light generated in the at least one organic functional stack. A transparent electrode can for example comprise a transparent conductive oxide or consist of a transparent conductive oxide. Transparent conductive oxides (“TCO”) are transparent, conductive materials, generally metal oxides such as, for example, zinc oxide, tin oxide, cadmium oxide, titanium oxide, indium oxide, indium zinc oxide (IZO) or indium tin oxide (ITO). Alongside binary metal-oxygen compounds such as, for example, titanium oxide, ZnO, SnO₂ or In₂O₃ ternary metal-oxygen compounds such as, for example, AlZnO, Zn₂SnO₄, CdSnO₃, ZnSnO₃, MgIn₂O₄, GaInO₃, Zn₂In₂O₅ or In₄Sn₃O₁₂ or mixtures of different transparent conductive oxides also belong to the group of TCOs. Furthermore, the TCOs do not necessarily correspond to a stoichiometric composition and can also be p- or n-doped.

In accordance with a further embodiment, at least one of the first and second electrodes can comprise a metal or be composed thereof. By way of example, the metal can be selected from aluminum, barium, indium, silver, gold, magnesium, calcium, lithium and compounds, combinations and alloys thereof. An electrode which comprises a metal or is composed thereof can be for example reflective to the light generated in the at least one organic functional stack. As an alternative thereto, the metal can be embodied as a layer having a sufficiently small thickness, such that the metal is at least partly transparent. Furthermore, an electrode can also comprise at least one layer composed of a TCO and at least one layer composed of a, preferably transparent, metal. Furthermore, at least one electrode can comprise at least two layers composed of a TCO, between which at least one metal layer, preferably a transparent metal layer, is arranged. In further embodiments, the first and/or the second electrode can comprise one or a plurality of the following materials as an alternative or in addition to the materials mentioned: networks composed of metallic nanowires and/or nanoparticles, for example composed of Ag; networks composed of carbon nanotubes; graphene particles or layers; networks composed of semiconducting nanowires. Furthermore, these electrodes can comprise conductive polymers or transition metal oxides or conductive transparent oxides.

At least one of the first and second electrodes is embodied as an anode, while the other of the first and second electrodes is embodied as a cathode. If the organic electroluminescent component is embodied as a “bottom emitter”, then the organic electroluminescent component comprises in particular a transparent substrate, as described above, and a transparent first electrode between the substrate and the at least one organic functional stack. If the organic electroluminescent component is embodied as a so-called “top emitter”, that is to say that the organic electroluminescent component emits light in a direction facing away from the substrate, then in particular the second electrode, arranged above the at least one organic functional stack as seen from the substrate, is embodied as transparent. In the “bottom emitter” or “top emitter” configuration, the respective other electrode can be embodied as reflective. If the organic electroluminescent component is embodied as a transparent or translucent component, the first and second electrodes are both embodied as transparent or translucent.

In accordance with a further embodiment, the organic electroluminescent component comprises at least two organic functional stacks. That can mean, in particular, that the organic electroluminescent component comprises a first organic functional stack, on which a second organic functional stack is arranged. The at least two organic functional stacks can in this case each have features in accordance with the abovementioned embodiments. In particular, the at least two organic functional stacks can be arranged between a first and a second electrode, such that the first organic functional stack and the second organic functional stack arranged thereon are connected in series one behind the other between the first and second electrodes.

In accordance with a further embodiment, the organic electroluminescent component comprises at least two organic functional stacks, of which a first organic functional stack has at least one first electroluminescent layer and at least one n-doped organic layer, while a second organic functional stack has at least one second electroluminescent layer and at least one p-doped organic layer. Furthermore, the first and second organic functional stacks can have even further functional layers mentioned previously. The first and second organic functional stacks can be arranged one on top of another in particular in such a way that the n-doped organic layer of the first organic functional stack and the p-doped organic layer of the second organic functional stack face one another and are arranged between the first and second electroluminescent layers.

In accordance with a further embodiment, the organic electroluminescent component comprises a metal layer between the first and second organic functional stacks. The metal layer can be arranged in particular between the n-doped organic layer of the first organic functional stack and the p-doped organic layer of the second organic functional stack in a manner directly adjacent thereto between the two organic functional stacks. Such a combination of adjacent n- and p-doped organic layers with a metal layer arranged therebetween can form a charge generation layer (CGL) or charge generation unit (CGU). By means of a charge generation layer of this type, organic functional stacks that are adjacent to one another can be electrically connected to one another, wherein charge carriers can be injected into the adjacent organic functional stacks through the charge generation layer. It has been found that a high voltage stability and thus a high lifetime of the organic electroluminescent component can be achieved in particular by the embodiment of a charge generation layer with a metal layer. By arranging the metal layer in the charge generation layer, it is possible to achieve a reduction in the necessary operating voltage since the metal serves as an additional charge carrier reservoir and thus facilitates the injection of charge carriers into adjacent organic functional stacks. Furthermore, undesired chemical reactions between the n- and p-doped layers which would lead to an additional barrier and thus to a voltage rise can be avoided by means of the metal layer.

In accordance with a further embodiment, the organic electroluminescent component comprises at least three organic functional stacks, wherein, of organic functional stacks that are in each case directly adjacent to one another, one has a p-doped organic layer and one has an n-doped organic layer, which are arranged between the respective electroluminescent layers of the two functional stacks and between which a metal layer is arranged in a directly adjacent manner.

By stacking one above another at least two organic functional stacks or at least three organic functional stacks with metal layers arranged therebetween, it is possible to achieve, with practically the same efficiency and identical luminance, significantly longer lifetimes compared with simple OLEDs comprising only one electroluminescent layer or one electroluminescent layer stack between n-doped and p-doped layers between the electrodes. The n-doped and p-doped organic layers and the metal layer form between the organic functional stacks in each case charge generation layers which enable efficient charge carrier injection into the organic functional stacks and thus lead to a low current density and a high voltage stability even in the case of a stacking of at least two or at least three organic functional stacks. In this case, the operating voltage scales linearly with the number of organic functional stacks.

According to a further embodiment, the first electroluminescent layer and the second electroluminescent layer can emit light having the same wavelength or having different wavelengths. As a result, depending on the embodiment of the metal layer and of the electrodes, in accordance with the following exemplary embodiments, identical or different-colored single- or mixed-colored light can be emitted at one or at both sides of the organic electroluminescent component.

In accordance with a further embodiment, the metal layer is floating (free of potential). That means that the metal layer has no connection and no possibility of contact toward the outside, for example to an external current and/or voltage source, and is not or cannot be applied to an external electrical potential. In particular, the metal layer accordingly cannot be contact-connectable. Rather, the metal layer is a layer which is arranged between the first and second organic functional stacks and which, as described above, serves for charge carrier injection together with the directly adjacent p-doped and n-doped layers and thus for series interconnection of the first and second organic functional stacks. Furthermore, in accordance with a further embodiment, the metal layer is not embodied as a substrate and in particular cannot serve as a substrate of one or both organic functional stacks. That can mean, for example, that the metal layer has a thickness that does not suffice for ensuring a sufficient load carrying strength and stability that would be necessary in order to serve as a substrate.

In accordance with a further embodiment, the metal layer comprises aluminum and/or silver or consists thereof. Metals such as aluminum and silver have a high electrical conductivity and, depending on the thickness of the metal layer, a high reflectivity for example for light in the visible spectral range. Given a sufficiently small thickness, the metal layer composed of silver and/or aluminum can also be at least partly transparent.

In accordance with a further embodiment, the metal layer is at least partly transparent. That can mean, in particular, that light generated by the first electroluminescent layer in the first organic functional stack can be radiated at least partly through the metal layer and can, for example, furthermore also be radiated through the second organic functional stack. Conversely, in the case of an at least partly transparent metal layer, light from the second organic functional stack and in particular from the second electroluminescent layer can be radiated through the metal layer into and furthermore also for example through the first organic functional stack. For this purpose, the metal layer can preferably have a thickness of less than or equal to 10 nm, in particular in the case of a metal layer which comprises aluminum and/or silver or is composed thereof.

In accordance with a further embodiment, the first and second electrodes, between which the first and second organic functional stacks and the metal layer are arranged, can be transparent. In particular in conjunction with an at least partly transparent metal layer, the organic electroluminescent component can thus be transparent in a switched-off state. In a switched-on state, the first and second organic functional stacks can emit light both through the substrate and through the second electrode arranged in a manner facing away from the substrate, such that a mixed-colored luminous impression can arise depending on the transparency of the metal layer and of the electrodes on both sides. Depending on the transparency of the metal layer, for example, the luminous impression on the substrate side and the luminous impression on the side opposite the substrate can be slightly different or else identical.

In accordance with a further embodiment, the metal layer is non-transparent. In particular, the metal layer in this case is embodied as reflective, such that light which is generated in the first electroluminescent layer and is emitted in the direction of the metal layer is reflected back from the latter. Likewise, by means of the non-transparent and preferably reflective metal layer, light which is formed in the second electroluminescent layer can be reflected by the metal layer. Particularly preferably, the first and second electrodes, between which the first and second organic functional stacks and the metal layer are arranged, are transparent in this case. By means of the non-transparent and preferably reflective metal layer between the first and second functional stacks, the luminous impressions on the two sides of the organic electroluminescent component, that is to say on the substrate side and the side opposite the substrate, can be set separately from one another. However, for this purpose it is not necessary to operate the two organic functional stacks separately from one another. Rather, on account of the n-doped and p-doped organic layers of the organic functional stacks and on account of the metal layer between them, it is possible to operate the two organic functional stacks in series. In a switched-off state, the organic electroluminescent component comprising a non-transparent and preferably reflective metal layer appears non-transparent and preferably specularly reflective.

In accordance with a further embodiment, the non-transparent metal layer has a thickness of greater than or equal to 20 nm and comprises aluminum as material. As an alternative of the two, the non-transparent metal layer can for example also comprise silver having a thickness of greater than or equal to 40 nm and particularly preferably of greater than or equal to 50 nm. In accordance with a further embodiment, the metal layer has a thickness of less than or equal to 200 nm.

Such thicknesses in conjunction with the materials mentioned can be sufficient to enable a sufficiently high reflectivity and a non-transmissivity to light, while the material outlay for the metal layer and thus also the outlay on costs can be kept low.

In accordance with a further embodiment, the metal layer is embodied as non-transparent and the first electroluminescent layer and the second electroluminescent layer emit light having different wavelengths. By way of example, the first organic functional stack can emit white light by virtue of a suitable selection of materials in the first electroluminescent layer and/or by virtue of suitable multilayer combinations for the first electroluminescent layer, while the second electroluminescent layer can emit colored light, for example red, green or blue light or mixtures thereof. Furthermore, it is also possible for both organic functional stacks to emit white light having identical or different white shades or color temperatures. Different emission of light toward both sides of the organic electroluminescent component is advantageously possible by virtue of the fact that the metal layer is non-transparent and preferably reflective, such that the respective emitted color or the luminous impression respectively emitted is dependent only by virtue of the type, quantity and arrangement of the respective electroluminescent layers of the organic functional stacks arranged on the two sides of the metal layer. An organic electroluminescent component of this type can for example advantageously be used as a lighting device for simultaneous direct and indirect lighting. For this purpose, one of the two organic functional stacks generates light, in particular white light, having a color and color temperature desired for direct lighting, while the second organic functional stack generates light that is desired or suitable for indirect lighting. The non-transparent metal layer between the organic functional stacks can ensure that the respective light can be emitted separately from one another.

The direct lighting can serve for room lighting, for example, while the indirect lighting serves as ceiling or wall lighting and in this case enables for example desired colored lighting of the ceiling or wall, respectively.

In accordance with a further embodiment, the metal layer is embodied as partly reflective. That can mean, in particular, that the metal layer is also embodied as partly transparent. In the case of such an embodiment of the metal layer, the latter can still be thin enough to allow light to radiate partly from one organic functional stack into the other organic functional stack, while part of the light generated in the organic functional stacks is in each case also reflected at the metal layer.

In accordance with a further embodiment, the first and second organic functional stacks with a partly reflective and partly transparent metal layer arranged therebetween are arranged between a first and a second electrode, wherein the first electrode is transparent and the second electrode is reflective and non-transparent. In this case, the transparent first electrode can be arranged for example between the organic functional stacks and the substrate. As an alternative thereto, the first, transparent electrode can for example also be arranged above the organic functional stacks as seen from the substrate. As a result, the organic electroluminescent component is embodied as a “bottom emitter” in the first case and as a “top emitter” in the second case.

The reflective second electrode and the partly reflective metal layer, between which, for example, the second organic functional stack can be arranged, can form an optical cavity. This optical cavity is coupled to the first organic functional stack by the partly reflective and partly transparent metal layer, this also being designated as a so-called “coupled micro-cavity”. By virtue of the second electroluminescent layer in the optical cavity, light can be emitted with a wavelength optimally set to a desired color, as a result of which, for example, the color rendering index of the organic electroluminescent component can be significantly increased in comparison with known OLEDs. The light generated in the optical cavity can be radiated back on account of the reflective second electrode through the partly transparent metal layer into the first organic functional stack, which can form a so-called main cavity, such that through the first transparent electrode mixed-colored light, consisting of the light generated in the first organic functional stack and the light generated in the second organic functional stack, can be emitted.

The formation of optical cavities is possible by virtue of a suitable choice of the transparency and reflectivity of the first and second electrodes even in the case of a non-transparent metal layer and in the case of a very thin metal layer having the highest possible transparency, wherein no optical coupling is present in the case of a non-transparent metal layer.

The introduction of the metal layer in the form of a transparent, a partly transparent and partly reflective or else a non-transparent and preferably reflective metal layer into the charge generation layer affords the possibility of achieving different emission properties of the organic electroluminescent component. In this case, it is possible to achieve emission either in both directions or in one direction of the organic electroluminescent component. In addition to the resultant freedoms in the color design of the organic electroluminescent component, the metal layer makes it possible to achieve a reduction in the operating voltage and an increase in the voltage stability of the organic functional stacks and thus of the organic electroluminescent component.

In accordance with a further embodiment, the organic electroluminescent component comprises an encapsulation layer. By way of example, the at least two organic functional stacks or else the at least three organic functional stacks can be arranged between a substrate and an encapsulation layer. The substrate and the encapsulation layer can be designed to protect the organic functional stacks and the metal layer or metal layers arranged therebetween against moisture, oxygen and other harmful substances. Furthermore, it is also possible for a further encapsulation layer to be arranged for example between the substrate and the organic functional stacks. Said further encapsulation layer can be designed to protect the organic functional stacks against harmful substances which might penetrate into the organic electroluminescent component for example through a substrate that is not hermetically sealed.

In accordance with a further embodiment, an encapsulation layer is embodied as thin-film encapsulation. That can mean, in particular, that the encapsulation layer comprises at least one and preferably a plurality of deposited layers which in each case by themselves or at least in combination with one another have a sufficient impermeability toward harmful substances. For this purpose, the encapsulation layer can comprise one or a plurality of layers composed of one or a plurality of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and combinations, mixtures and alloys thereof. The encapsulation layer can be applied by an atomic layer deposition method, for example, by means of which highly impermeable layers composed of at least some of the materials mentioned above can be produced. In particular, the encapsulation layer can in this case also be transparent, such that the emission properties of the organic electroluminescent component are not influenced or are only slightly influenced by the encapsulation layer.

In accordance with a further embodiment, the encapsulation layer can comprise a glass layer. The glass layer can be embodied as a glass plate or glass substrate, for example, which together with a substrate can form a closed-off cavity in which the organic functional stacks, the electrodes and the metal layer or the metal layers are arranged. By way of example, the glass layer can have a cavity or depression which can be produced by means of etching, for example, and in which a material that can physically or chemically bind harmful substances can also be arranged, for example. Such a material is also referred to as a Getter material and is known to the person skilled in the art.

In accordance with a further embodiment, the organic electroluminescent component comprises a cover layer on the side facing away from the substrate. The cover layer can for example comprise glass or a plastic or be composed thereof.

In accordance with a further embodiment, the organic electroluminescent component comprises at least one transparent first and/or second electrode on which a light coupling-out element is arranged on a side facing away from the metal layer. The light coupling-out element can be embodied for example in the form of a layer or in the form of individual elements or particles which can be light-scattering or light-refracting. By way of example, the light coupling-out element can be embodied as a scattering film, as a micro-lens array or as surface structuring of an additional transparent layer or else of the substrate, of an encapsulation layer or of a cover layer.

Further advantages and advantageous embodiments and developments will become apparent from the embodiments described below in conjunction with the figures.

In the figures:

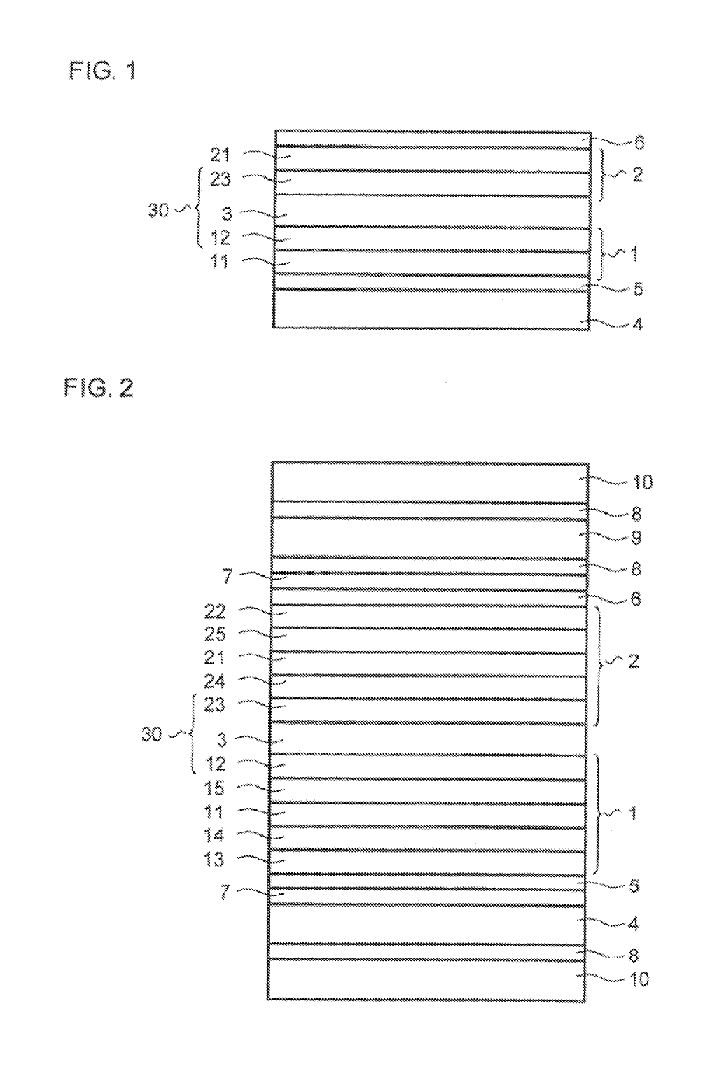

FIG. 1 shows a schematic illustration of an organic electroluminescent component in accordance with one exemplary embodiment,

FIGS. 2 to 4 show schematic illustrations of organic electroluminescent components in accordance with further exemplary embodiments, and

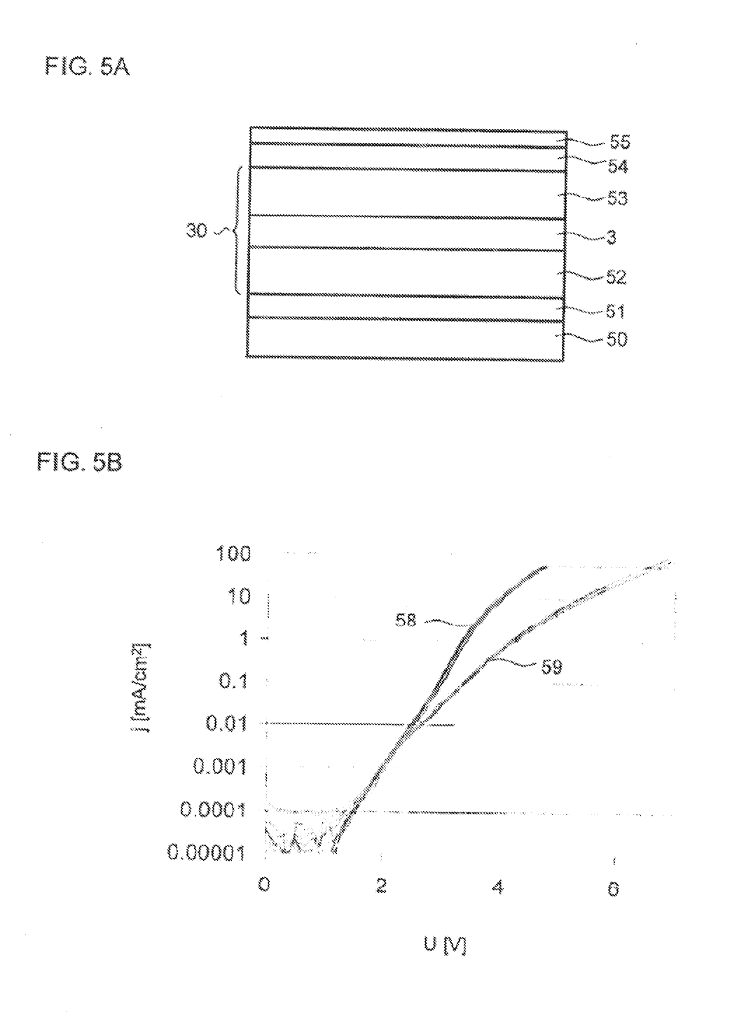

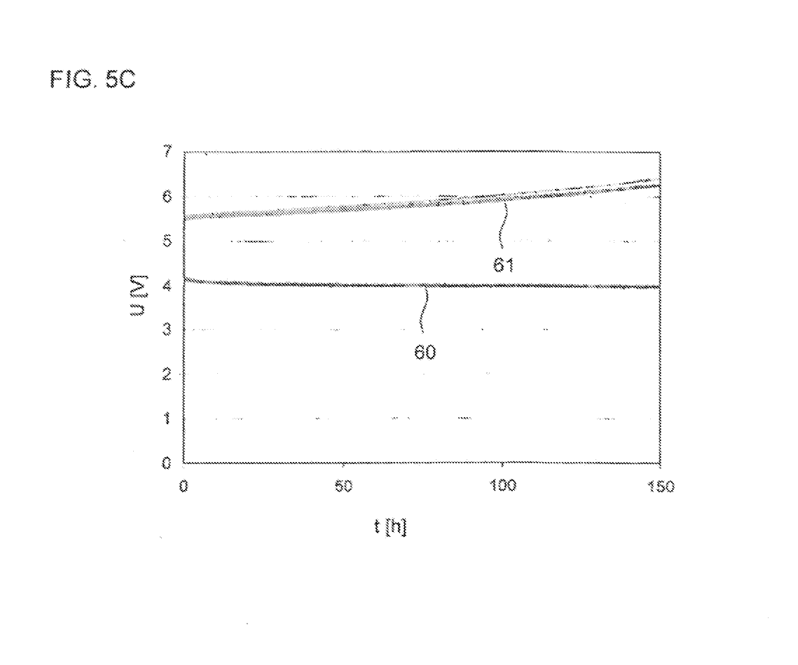

FIGS. 5A to 5C show a test structure and electrical properties thereof.

In the exemplary embodiments and figures, identical or identically acting constituent parts may in each case be provided with the same reference signs. The illustrated elements and their size relationships among one another should not be regarded as true to scale, in principle; rather, individual elements, such as e.g. layers, component parts, components and regions, may be illustrated with exaggerated thickness or size dimensions in order to enable better illustration and/or in order to afford a better understanding.

FIG. 1 shows an exemplary embodiment of an organic electroluminescent component comprising a first organic functional stack 1 and a second organic functional stack 2. A metal layer 3 is arranged between the two organic functional stacks 1 and 2.

The organic electroluminescent component furthermore comprises a substrate 4, on which are arranged the organic functional stacks 1 and 2 and the metal layer 3 between a first electrode 5 and a second electrode 6 for making the electrical contact with the functional stacks. The electrodes 5 and 6 and the layers of the organic functional stacks 1 and 2 can comprise materials as described in the general part.

At least one of the first and second electrodes 5 and 6 is embodied as transparent, wherein, at least in the case of the embodiment of the organic electroluminescent component as a bottom emitter comprising a transparent first electrode 5, the substrate 4 is also embodied as transparent.

The first organic functional stack 1 has at least one first electroluminescent layer 11 and at least one n-doped organic layer 12. The second organic functional stack 2 has at least one second electroluminescent layer 21 and at least one p-doped organic layer 23.

Purely by way of example, in the exemplary embodiment shown, the first electrode 5 is embodied as an anode and the second electrode 6 is embodied as a cathode. As an alternative thereto, an opposite arrangement of the first and second electrodes is possible, wherein, in this case, the dopings of the organic functional stacks 1 and 2 are also opposite to the exemplary embodiment shown.

The n-doped organic layer 12 and the p-doped organic layer 23 are arranged between the electroluminescent layers 11 and 21 and in each case are directly adjacent to a metal layer 3 situated therebetween. As described in the general part, the n-doped and p-doped organic layers 12 and 23 together with the metal layer 3 form a charge generation layer 30. The metal layer 3 is arranged in a floating manner and does not have a dedicated contact with an external current and/or voltage supply. In the exemplary embodiment shown, the metal layer 3 can comprise aluminum and/or silver or be composed thereof.

The effect of the metal layer 3 in a charge generation layer 30 is shown in conjunction with FIGS. 5A and 5B. For this purpose, as shown in FIG. 5A, a test structure was produced, comprising, on a substrate 50, an n-doped organic layer 52, a metal layer 3 and thereabove a p-doped organic layer 53 as charge generation layer 30 between two undoped organic layers 51 and 54. In the test structure, the substrate 50 comprised a glass plate and thereon a first electrode composed of indium tin oxide (ITO). A second electrode 55 composed of metal is applied above the organic layers 51 to 54 and the metal layer 3.

FIG. 5B shows a voltage-current density diagram with the voltage U in volts on the horizontal axis and the current density J in mA/cm² on the vertical axis. In this case, the voltage-current density curve 58 was measured with a test structure in accordance with FIG. 5A. In comparison therewith, the voltage-current density curve 59 of a comparative structure that did not have a metal layer 3 is shown. As can readily be discerned from FIG. 5B, with the charge generation layer 30 with the metal layer 3 as described here it is possible to achieve a higher current density for an identical voltage in comparison with a comparative structure without a metal layer 3.

FIG. 5C shows the operating voltage of a test structure in accordance with FIG. 5A in a time period of 150 hours by means of the curve 60. In comparison therewith, as is shown by means of the curve 61, a rise in the operating voltage in the same time period was measured for a comparative structure without a metal layer 3. Therefore, whereas with a test structure in accordance with FIG. 5A with the metal layer 3 a stable charge generation layer 30 was achieved during the test operating duration of 150 hours, increases in the operating voltage by more than 1 V were measured in the case of comparative structures without a metallic intermediate layer. The insights gained by means of the test structure from FIG. 5A are at least qualitatively directly applicable to the organic electroluminescent components shown in conjunction with FIGS. 1 to 4.

FIGS. 2 to 4 show further organic electroluminescent components representing modifications of the exemplary embodiment shown in FIG. 1.

The organic electroluminescent component in accordance with the exemplary embodiment in FIG. 2 comprises a first organic functional stack 1, thereabove a metal layer 3 and above the latter a second organic functional stack 2 on a substrate 4 between a first electrode 5 and a second electrode 6. As in the exemplary embodiment in accordance with FIG. 1, the first organic functional stack 1 has an n-doped organic layer 12 and the second organic functional stack 2 has a p-doped organic layer 23, in each case directly adjacent to the metal layer 3, whereby a charge generation layer 30 is formed.

In the exemplary embodiment shown, the substrate 4 is composed of glass or a plastic film. The plastic film can furthermore comprise or be formed from, for example, polyolefins, for instance high or low density polyethylene (PE) or polypropylene (PP). Furthermore, the plastic can comprise or be formed from polyvinyl chloride (PVC), polystyrene (PS), polyester and/or polycarbonate (PC), polyethylene terephthalate (PT), polyether sulfone (PES) and/or polyethylene naphthalate (PEN).

In the exemplary embodiment shown, the first electrode 5 is embodied as a transparent anode, on which the first organic functional stack 1 is arranged, and comprises a thin metal film or a transparent conductive oxide, for example indium tin oxide, indium zinc oxide or zinc oxide.

In the exemplary embodiment shown, the first organic functional stack 1 has, as seen from the first electrode 5, a p-doped organic layer 13, which is embodied as a hole transport layer, thereabove an electron blocking layer 14, thereabove the first electroluminescent layer 11, which, as an alternative to the exemplary embodiment shown, can also comprise a plurality of electroluminescent layers, thereabove a hole blocking layer 15 and thereabove the previously described n-doped organic layer 12, which is embodied as an electron transport layer in the exemplary embodiment shown.

The second organic functional stack 2 has a similar construction, which comprises the above-described p-doped organic layer 23 in the form of a hole transport layer, an electron blocking layer 24, a second electroluminescent layer 21, which, as an alternative to the exemplary embodiment shown, can also comprise a plurality of electroluminescent layers, thereabove a hole blocking layer 25 and thereabove an n-doped organic layer 22, which is embodied as an electron transport layer. The electroluminescent layers 11 and 21 can generate identical or different light, depending on what kind of luminous impression is desired on the two sides of the organic electroluminescent component, that is to say on the side having the substrate 4 and on the side having the second electrode 6.

In the exemplary embodiment shown, the metal layer 3 is embodied as non-transparent and reflective. For this purpose, the metal layer 3 comprises aluminum and/or silver or is composed thereof. In the case of silver, the metal layer has a thickness of greater than or equal to 40 nm and preferably of greater than or equal to 50 nm. In the case of aluminum, the metal layer 3 has a thickness of greater than or equal to 20 nm. Particularly preferably, the metal layer 3 has a thickness of less than or equal to 200 nm.

The second electrode 6, which is arranged above the second organic functional stack 2 on that side of the metal layer 3 which faces away from the substrate 4, is likewise embodied as a transparent electrode which is at least partly transparent to the light generated in the second organic functional stack 2. Furthermore, in the exemplary embodiment shown, the second electrode 6 is embodied as a cathode and comprises a thin metal film or a transparent conductive oxide, as described for example in conjunction with the first electrode 5. As an alternative to the exemplary embodiment shown, the first electrode 5 and/or the second electrode 6 can also be embodied as multilayered and comprise or be composed of, for example, one or a plurality of TCO layers and/or one or a plurality of metal layers and/or one or a plurality of the further materials mentioned in the general part.

By virtue of the non-transparent metal layer 3 between the first and second organic functional stacks 1 and 2, the organic electroluminescent component shown in FIG. 2 can emit light through the substrate 4 and the first electrode 5 and through the second electrode 6 independently of one another and is thus embodied as a so-called bidirectionally emitting OLED.

Furthermore, the organic electroluminescent component can comprise encapsulation layers 7 as shown in the exemplary embodiment, wherein the organic functional stacks 1 and 2 and the metal layer 3 are arranged between an encapsulation layer 7, arranged on the second electrode 6, and the substrate 4. In order to increase the impermeability of the substrate 4, a further encapsulation layer 7 is arranged between the substrate 4 and the first electrode 5.

In the exemplary embodiment shown, the encapsulation layers 7 are transparent and are embodied as so-called thin-film encapsulation. They are produced by a deposition method, for example an atomic layer deposition (ALD) method, and comprise one or a plurality of layers composed of one or a plurality of the materials mentioned in the general part.

Above the second electrode 6 and the encapsulation layer 7 arranged thereabove, a cover layer 9 is arranged by means of an adhesive layer 8, said cover layer being composed, for example, of a glass or a plastic film composed of one of the plastic materials mentioned above. In this case, the cover layer 9 serves in particular as scratch protection and need not be embodied in a hermetically sealed fashion on account of the encapsulation layer 7 on the second electrode 6.

Above the cover layer 9 and on that side of the substrate 4 which faces away from the organic functional stacks 1 and 2, a light coupling-out element 10 in the form of a scattering film, a micro-lens array or a layer having a surface structuring is arranged in each case by means of a further adhesive layer 8. As an alternative thereto, the substrate 4 and/or the cover layer 9 can also be provided with a surface structuring as light coupling-out element 10.

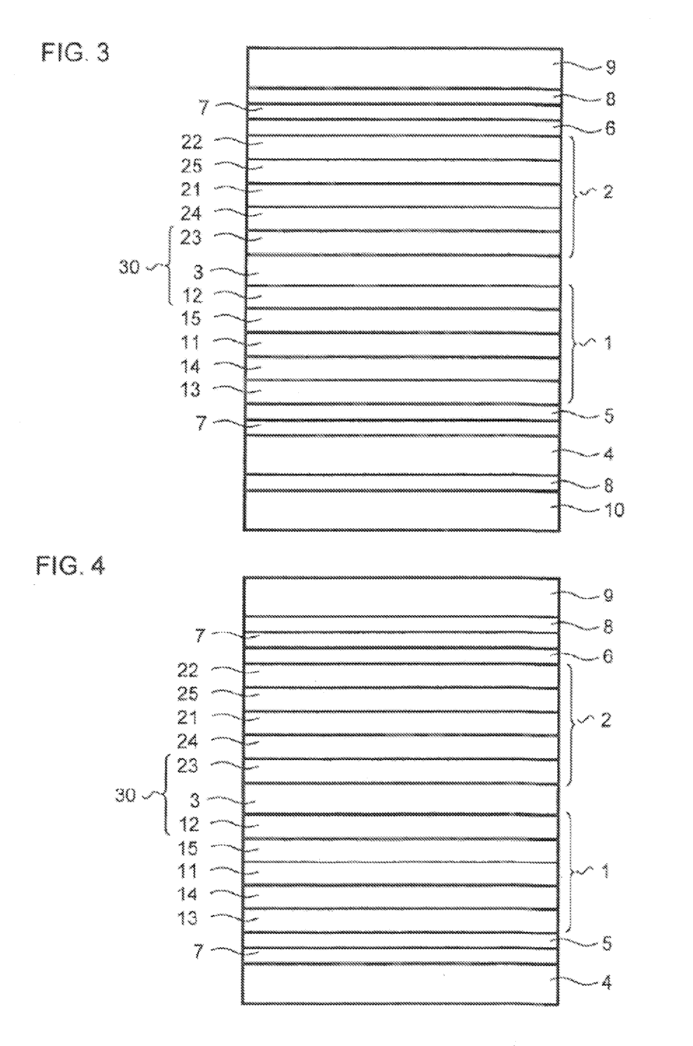

FIG. 3 shows, in comparison with the exemplary embodiment in FIG. 2, an organic electroluminescent component comprising a metal layer 3 which is partly transparent and partly reflective. Furthermore, in the exemplary embodiment shown, the second electrode 6 is embodied as a reflective metal layer. As a result, as described in the general part, the second organic functional stack 2 forms a micro cavity that is optically coupled to the first organic functional stack 1. For this purpose, the metal layer 3 comprises for example silver having a thickness of greater than or equal to 10 nm and less than or equal to 40 nm or aluminum having a thickness of greater than or equal to 10 nm and less than or equal to 20 nm.

The coupled cavity formed by the second organic functional stack 2 and the first organic functional stack 1 can be optimally oriented toward a desired color by the setting of the materials of the organic layers 11 to 15 and 21 to 25 and their thicknesses and arrangement with respect to one another, such that the light which is emitted through the substrate 4 and which is a superimposition of the light formed in the first organic functional stack 1 and the light formed in the second organic functional stack 2 can have a high color rendering index.

As in the previous exemplary embodiment, the encapsulation layer 7 arranged on the second electrode can be embodied as thin-film encapsulation. As an alternative thereto, the encapsulation layer 7 on the second electrode 6 can for example also be embodied as a glass layer in the form of a glass plate or a glass substrate, which can furthermore also have a cavity or depression, for example in the form of an etched cavity, with a getter material. In the case of a transparent organic electroluminescent component or organic electroluminescent component embodied as a top emitter, the Getter material in this case is preferably formed around the active region of the organic functional stacks. In the case of a glass plate as encapsulation layer 7, the cover layer 9 shown in FIG. 3 and also the adhesive layer 8 between the cover layer 9 and the encapsulation layer 7 can also be omitted.

FIG. 4 shows a further exemplary embodiment of an organic electroluminescent component, which, in comparison with the exemplary embodiments in FIGS. 2 and 3, comprises a metal layer 3 having a thickness of less than or equal to 10 nm. As a result, the metal layer 3 is at least partly transparent. The electrodes 5 and 6 are likewise embodied as transparent, such that the radiation generated in each case in the organic functional stacks 1 and 2 can be emitted by the organic electroluminescent component on both sides. In this case, depending on the transparency of the electrodes 5 and 6 and of the metal layer 3, an identical color impression or else a slightly different color impression can be made possible on both sides. In the switched-off state, the organic electroluminescent component in accordance with FIG. 4 appears transparent. In addition, light coupling-out elements, as shown in conjunction with FIGS. 2 and 3, can also be arranged on one or both sides of the organic electroluminescent component. As a result, the organic electroluminescent component can appear translucent in the switched-off state.

In addition to the exemplary embodiments shown, an organic electroluminescent component can also comprise a combination of the features of the exemplary embodiments shown. Thus, by way of example, it can also be possible for an organic electroluminescent component to comprise at least three organic functional stacks between which a respective metal layer is arranged. N-doped and p-doped layers together with the metal layer situated therebetween and in each case directly adjacent thereto between the individual organic functional stacks in this case form charge generation layers, while the individual metal layers can be configured identically or differently from one another. Thus, by way of example, it can be possible for an organic electroluminescent component to comprise a first metal layer, which is non-transparent and reflective, while a second metal layer is at least partly transparent. Consequently, at least one organic functional stack can be arranged on one side of the reflective, non-transparent metal layer, while for example at least two organic functional stacks are arranged on the other side. The two organic functional stacks with the at least partly transparent metal layer arranged therebetween can form for example a coupled micro-cavity, as described in conjunction with FIG. 3.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1. An organic electroluminescent component comprising:
a first organic functional stack, which has a first electroluminescent layer and at least one n-doped organic layer; and,
a second organic functional stack, which has a second electroluminescent layer and at least one p-doped organic layer,
wherein the n-doped and p-doped organic layers are arranged between the first and second electroluminescent layers, and a metal layer is arranged therebetween in a manner directly adjacent to the n-doped and p-doped organic layers.

2. The organic electroluminescent component according to claim 1, wherein the metal layer is floating.

3. The organic electroluminescent component according to claim 1, wherein the metal layer is not contact-connectable.

4. The organic electroluminescent component according to claim 1, wherein the metal layer comprises aluminum or silver or is composed thereof.

5. The organic electroluminescent component according to claim 1, wherein the metal layer is at least partly transparent.

6. The organic electroluminescent component according to claim 1, wherein the metal layer is non-transparent and reflective.

7. The organic electroluminescent component according to claim 6, wherein the first and second organic functional stacks are arranged between a first and a second electrode, and
wherein the first and second electrodes are transparent.

8. The organic electroluminescent component according to claim 1, wherein the metal layer is partly transparent and partly reflective.

9. The organic electroluminescent component according to claim 8, wherein the first and second organic functional stacks are arranged between a first and a second electrode, and
wherein the first electrode is transparent and the second electrode is reflective and non-transparent.

10. The organic electroluminescent component according to claim 1, further comprising a transparent first or second electrode having a layer comprising a transparent conductive oxide or a transparent metal layer.

11. The organic electroluminescent component according to claim 1, wherein the first and second organic functional stacks are arranged between a substrate and an encapsulation layer.

12. The organic electroluminescent component according to claim 11, wherein the encapsulation layer is embodied as thin-film encapsulation.

13. The organic electroluminescent component according to claim 11, wherein the encapsulation layer comprises a glass layer.

14. The organic electroluminescent component according to claim 1, wherein a light coupling-out element is arranged on a side of a transparent first or a second electrode that faces away from the metal layer.

15. An organic electroluminescent component comprising:
a first organic functional stack, which has a first electroluminescent layer and at least one n-doped organic layer; and
a second organic functional stack, which has a second electroluminescent layer and at least one p-doped organic layer,
wherein the n-doped and p-doped organic layers are arranged between the first and second electroluminescent layers, and a metal layer is arranged therebetween in a manner directly adjacent to the n-doped and p-doped organic layers,
wherein the metal layer is floating and not contact-connectable, and
wherein the metal layer is non-transparent and reflective.

16. An organic electroluminescent component comprising:
a first organic functional stack, which has a first electroluminescent layer and at least one n-doped organic layer; and
a second organic functional stack, which has a second electroluminescent layer and at least one p-doped organic layer,
wherein the n-doped and p-doped organic layers are arranged between the first and second electroluminescent layers, and a metal layer is arranged therebetween in a manner directly adjacent to the n-doped and p-doped organic layers,
wherein the metal layer is floating and not contact-connectable, and
wherein the metal layer is partly transparent and partly reflective.
